(19) United States
(12) Patent Application Publication
(10) Pub. No.: US 2008/0298935 A1
(43) Pub. Date: Dec. 4, 2008

(54) Wafer Cassette, Wafer Cassette Pod and Minienvironment Chamber Loadport Arrangement with a Minienvironment Chamber and a Wafer Cassette Pod with a Wafer Cassette

(76) Inventor: Michael Lering, Dresden (DE)

Correspondence Address: SLATER & MATSIL, L.L.P., 17950 PRESTON ROAD, SUITE 1000, DALLAS, TX, 75252, US

(21) Appl. No.: 11/757,838

(22) Filed: Jun. 4, 2007

(51) Int. Cl. H01L 21/67

(52) U.S. Cl. 414/217.1

(57) ABSTRACT

Exemplary embodiments of the invention relate to a wafer cassette, to a wafer cassette pod and to a minienvironment chamber loadport arrangement with a minienvironment chamber and a wafer cassette pod. In one exemplary embodiment of the invention, a wafer cassette is provided which has a plurality of wafer supports for supporting wafers, with the wafer supports being designed such that the pitch between wafers supported by means of the wafer supports is variable.

### TECHNICAL FIELD

Exemplary embodiments of the invention relate to a wafer cassette, to a wafer cassette pod and to a minienvironment chamber loadport arrangement with a minienvironment chamber and a wafer cassette pod.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a plan view and FIGS. 1B and 1C show a schematic illustration of a wafer cassette in two different states from the side, according to one exemplary embodiment of the invention;

FIGS. 2A and 2B each shows a plan view of a schematically illustrated wafer cassette according to one embodiment of the invention;

FIG. 3 shows a schematic illustration of an expansion/collapsing structure according to one embodiment of the invention;

FIG. 4 shows a schematic illustration of an expansion/collapsing structure according to a further embodiment of the invention;

FIG. 5 shows a schematic illustration of an expansion/collapsing structure according to a further embodiment of the invention;

FIG. 6 shows a schematic illustration of an expansion/collapsing structure according to a further embodiment of the invention;

FIG. 7 shows a schematic illustration of an expansion/collapsing structure according to a further embodiment of the invention;

FIG. 8 shows a schematic illustration of an expansion/collapsing structure according to a further embodiment of the invention;

FIG. 9 shows a schematic illustration of an expansion/collapsing structure according to a further embodiment of the invention;

FIG. 10 shows a schematic illustration of a wafer cassette pod according to one embodiment of the invention; and

FIGS. 11A and 11B show a schematic illustration of a loadport with integrated minienvironment chamber arrangement according to one embodiment of the invention, wherein FIG. 11A shows an undocked wafer cassette pod and FIG. 11B shows a docked pod and out of pod lifted cassette.

### DETAILED DESCRIPTION OF ILLUSTRATIVE EMBODIMENTS

The handling and processing of semiconductor wafers require particular care, especially with regard to the avoidance of contamination. In order to keep the presence and production of contamination during storage and transportation of wafers outside and within a clean area, for example between individual process stations, as small as possible, wafers are stored, for example, in so-called FOUPs (Front Opening Unified Pods per, e.g., SEMI Standard E47.1) when using, for example, 300 mm wafer technology. A specific number of wafers can be stored on corresponding support sections, which are fixed in the FOUP, wherein the FOUP may be in the form of a so called minienvironment. The FOUPs can be transported to the individual process stations manually or by means of a transport device. Automated opening of the front door allows the wafer handling devices to have access to the individual wafers. A different wafer cassette pod which is normally used for 200 mm wafer technology is the so-called SMIF pod (standardized mechanical interface per, e.g., SEMI Standard E119.1-5), which can be closed, such that it is sealed, by a bottom door arranged at the bottom. No supporting sections for supporting wafers are provided in an SMIF pod and, in fact, an open wafer cassette is inserted into an SMIF pod. In order to process the wafers, the SMIF pod is docked with a minienvironment chamber interface SMIF loadport, the bottom door is opened and the wafer cassette is moved downwards into the minienvironment chamber by means of an interface device. The wafer cassette pods can be transported to the individual minienvironment chambers by means of an automated material transport system such as a conveyor or an overhead hoist.

The FOUP, or the wafer cassette inserted into an SMIF pod, should be designed such that the pitch between the wafers which have each been positioned adjacent to one another is designed to allow disturbance-free access, for example by means of robot arms, to the wafers for their removal from/insertion into the FOUP or from/into the wafer cassette without damaging a respectively adjacent wafer, for example by scratching. In this case, account should be taken of the fact that, for example, 300 mm wafers or wafers of the next wafer generation with a diameter of 450 mm, which are each supported by their bevels/edge exclusion zone in the FOUP or the wafer cassette, bend to a specific extent and, accordingly, the pitch between the shelf sections on which the wafers are supported have a predetermined pitch between them.

A number of wafers corresponding to a manufacturing batch are in each case inserted into a FOUP or into a wafer cassette which is inserted into an SMIF pod, with the maximum number of wafers which can be held in a FOUP or a SMIF pod being limited by the size (vertical height) of the FOUP or the size (vertical height) of the SMIF pod. By way of example, the size of a FOUP is governed by the FIMS port provided by the FOUP door, since it must be compatible with the interface, for example, of the minienvironment chambers in the process installation. A SMIF pod should be designed to be appropriately high in order to allow the wafer cassette to be used with the batch, with the SMIF pod for holding a wafer cassette with, for example, 450 mm wafers having to be made higher because of the pitches required between the wafers, than in the case, for example, of 300 mm wafers with the same batch size.

According to exemplary embodiments of the invention, an improved wafer cassette for insertion into, for example, a wafer cassette pod, a wafer cassette pod into which the improved wafer cassette can be inserted, and a minienvironment chamber arrangement with a minienvironment chamber and a wafer cassette pod with a wafer cassette are provided.

Furthermore, according to one exemplary embodiment of the invention, a wafer cassette with a plurality of wafer support structures is provided in order to support wafers, with the wafer support structures being designed such that the pitch between wafers supported by means of the wafer support structures is variable.

Furthermore, according to one exemplary embodiment of the invention, a wafer cassette pod is provided which is designed for docking, e.g., at a loadport in front of a minienvironment chamber and, with a wafer cassette being held, can be closed by means of a closure plate which is arranged on the wafer cassette, with the wafer cassette having a plurality of wafer support structures for supporting wafers, and with the wafer support structures each being coupled to an expansion/collapsing structure such that the pitch between wafers supported by means of the wafer support structures is variable. In an embodiment of the invention, the minienvironment chamber may be understood as being a localized environment created by an enclosure to isolate a product or process from the surrounding environment.

Furthermore, according to another exemplary embodiment of the invention, a minienvironment chamber arrangement, e.g., a tool frontend arrangement, is provided, having a minienvironment chamber which has a wafer cassette load port, and having a wafer cassette pod which is designed for docking with the wafer cassette load port, with the wafer cassette pod holding a wafer cassette which is provided with a plurality of wafer support structures for supporting wafers, with the wafer support structures being designed such that the pitch between wafers supported by means of the wafer support structures is variable.

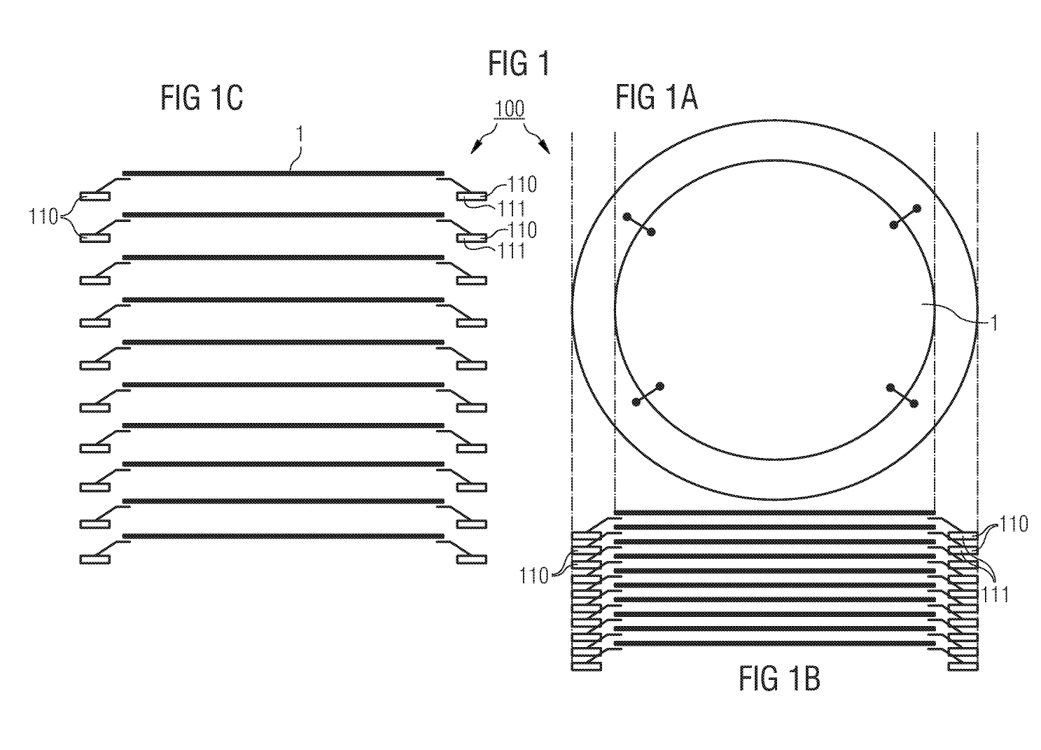

FIGS. 1A to 1C show schematic illustrations of a cassette, also referred to in the following text as the wafer cassette 100, in two different states according to one exemplary embodiment of the invention, with FIG. 1A showing a plan view of the wafer cassette 100, FIG. 1B showing the wafer cassette in a collapsed state, and FIG. 1C showing the wafer cassette in an expanded state.

According to one exemplary embodiment of the invention, the wafer cassette 100 has a plurality of wafer support structures 110 for supporting wafers 1, with the wafer support structures 110 being designed such that the pitch between wafers 1 supported by means of the wafer support structures 110 is variable.

According to one exemplary embodiment of the invention, the pitch of the wafers 1, which are in each case arranged adjacent to one another, can be varied between a collapsed state as shown in FIG. 1B and an expanded state as shown in FIG. 1C, and the wafer cassette 100 can be inserted into a wafer cassette pod (not illustrated) in the collapsed state. The wafer support structures 110 on which the wafers 1 are supported have a minimum pitch from one another when the wafer cassette 100 is in the collapsed state such that the wafers 1, which are arranged stacked one above the other, do not touch one another even at the point of maximum bending.

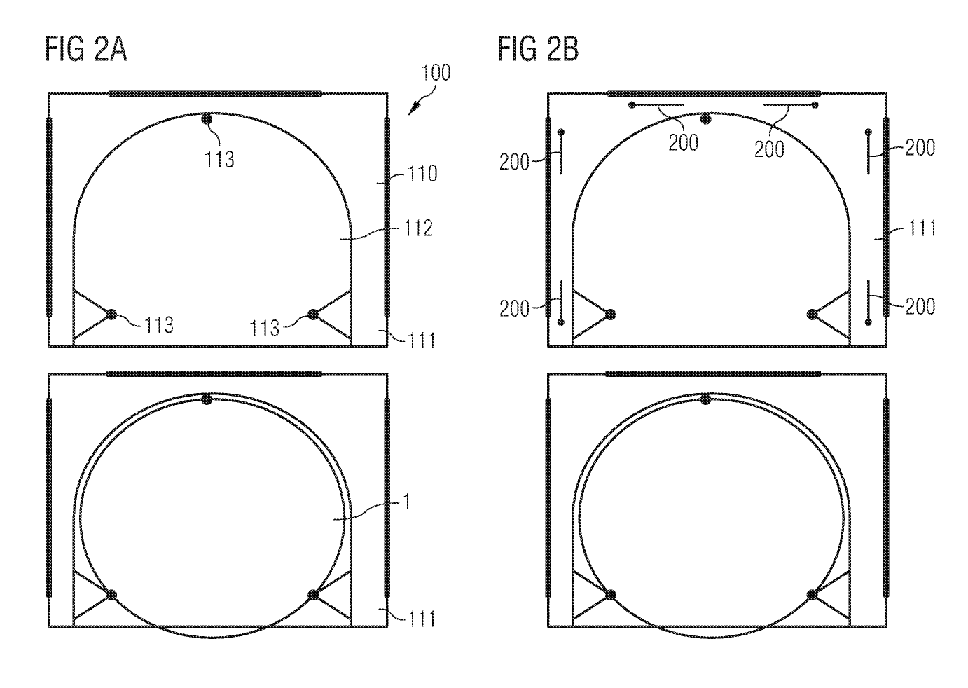

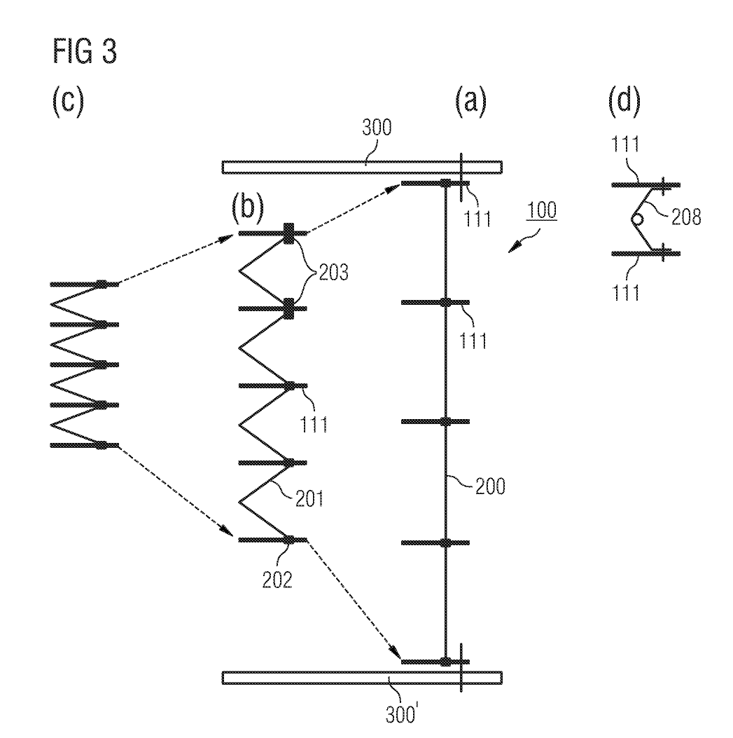

As can be seen from FIG. 2A, the wafer support structures 110 each have a shelf section 111 for supporting in each case one wafer 1, with the area between two mutually adjacent shelf sections 111 being a so-called slot. By way of example, the shelf sections 111 are formed from flat plates that are provided with a cutout 112, which essentially simulates the wafer 1, with rest sections 113 projecting from the edge bounding the cutout 112, on which rest sections 113 sections of the circumferential edge of the wafers 1 rest. An expansion/collapsing structure 200 (see, for example, FIG. 3) is in each case coupled between respectively mutually adjacent shelf sections 111, one of which forms a slot, such that the pitch between respectively mutually adjacent wafers 1 at right angles to the wafer surface is adjustable in a predetermined pitch range, or such that the size of the wafer cassette 100 at right angles to the wafer surface can be adjusted between a minimum extent (FIG. 1B) and a maximum extent (FIG. 1C).

In the collapsed state, the wafer cassette 100 can be held, stored and transported in a wafer cassette pod. When, for example, the wafer cassette 100 is removed from the wafer cassette pod for processing, the wafer cassette 100 can expand by means of the expansion/collapsing structure 200 between the shelf sections 111 of the wafer support structures 110, thus increasing the pitch between the shelf sections 111, and in consequence between the individual wafers 1. The maximum possible pitch which can be set between the wafers 1 may in this case be provided such that handling devices such as one or more end effectors of one or more robot arms can access the individual wafers 1, such that adjacent wafers 1 are not adversely affected. When the wafer cassette 100 has its maximum vertical extent, a pitch of more than 10 mm (e.g., for a usual pitch for a 300 mm wafer cassette), for example of a pitch of 11 mm to 20 mm, can in each case be set between the wafers 1 which, for example, are 300 mm or 450 mm wafers.

According to one embodiment of the invention, the wafer cassette 100 in consequence provides an improved wafer cassette 100 which on the one hand occupies a minimum amount of space for storage and transportation of wafers 1, since the wafer cassette 100 is collapsible and can be held in the collapsed state (see FIG. 1B) in a wafer cassette pod whose own vertical extent does not need to be enlarged in consequence, and which on the other hand can be unfolded (expanded) for processing of the wafers 1 (see FIG. 1C) when, for example, the wafer cassette 100 is moved from the wafer cassette pod to a minienvironment chamber. This refinement is advantageous for example for large wafers 1, that is to say for 300 mm wafers or 450 mm wafers, since a pitch of approximately 10 mm to approximately 16 mm between each of the individual wafers for handling and gripping such large wafers 1 should be provided, and according to one embodiment can be provided by means of the expanded wafer cassette 100, without having to provide more space or free space in the factory for storage and/or transportation of the wafer cassette pods in which the wafer cassettes are stored in the collapsed state.

As can also be seen from FIGS. 2A and 2B, the shelf sections 111 which are arranged vertically one above the other, for example, in the figures have a rectangular or square circumferential structure so that the shelf sections 111 arranged one above the other form a wafer cassette structure with an essentially square or rectangular cross section, which can be inserted into a corresponding internal area in a wafer cassette pod.

The shelf sections 111 which are arranged one above the other are, for example, coupled by means of the expansion/collapsing structure 200, with in each case at least one expansion/collapsing structure 200 being provided between each of the mutually adjacent shelf sections 111 according to one embodiment of the invention. However, it is also possible, as is illustrated in FIG. 2B, to position two or more such expansion/collapsing structures 200 between every two mutually adjacent shelf sections 111, for example being positioned uniformly in the circumferential direction of the wafers 1 so as to ensure an access area to the wafers 1 supported in the wafer cassette 100, without impeding removal/insertion of the wafers. The robustness of the shelf sections 111 with respect to one another and therefore the robustness of the wafer cassette 100 overall can be influenced by the arrangement of more than one expansion/collapsing structure 200 on each of the corresponding planes.

This expansion/collapsing structure 200 allows the pitch between the shelf sections 111 and therefore between the individual wafers 1 to be set precisely in a predetermined pitch range at right angles to the wafer surface.

According to one embodiment of the invention, one end section of the expansion/collapsing structure 200 is in each case supported on respectively mutually facing sides of two mutually adjacent shelf sections 111, as is shown in FIG. 3.

Sections of the wafer cassette 100 are illustrated schematically in FIG. 3, with the pitches between shelf sections 111 being illustrated with the wafer cassette 100 completely expanded in illustration (a), with the wafer cassette 100 half expanded/half collapsed in illustration (b), and with the wafer cassette 100 completely collapsed in illustration (c), by way of example. On the basis that the pitches shown in illustration (a) between the shelf sections 111 and thus between the individual wafers are intended for disturbance-free handling and gripping of the wafers during processing, for example even as a result of their natural bending, while in comparison illustration (c) shows that a shorter pitch is sufficient for transportation and storage of the wafers in a wafer cassette pod, it is possible to see the advantageous space saving that can be achieved when using the wafer cassette 100 according to one embodiment of the invention, when this wafer cassette 100 is inserted into a wafer cassette pod.

According to one embodiment of the invention, the expansion/collapsing structure 200 can be designed such that the expanded wafer cassette 100 describes a “normal state,” as is illustrated in illustration (a) in FIG. 3, that is to say the expansion/collapsing structure 200 is unloaded, and a pressure must be applied to the wafer cassette 100 in order to move this wafer cassette 100, as is illustrated in illustration (c) in FIG. 3, to a collapsed state, as can be done, for example, when the wafer cassette 100 is inserted into a wafer cassette pod. However, it is also possible to design the expansion/collapsing structure 200 such that the collapsed wafer cassette 100 describes a “normal state,” as is illustrated in the illustration (c) in FIG. 3, that is to say the expansion/collapsing structure 200 is unloaded, and a tensile force must be applied to the wafer cassette 100 in order to move this wafer cassette 100, as is illustrated in the illustration (a) in FIG. 3, to an expanded state, which can be done, for example, on removal of the wafer cassette 100 from a wafer cassette pod, and on insertion of the wafer cassette into a minienvironment chamber.

However, the expansion/collapsing structure 200 may also be designed such that the pitch between the shelf sections 111 is changed by the force of gravity, for example on gripping the upper section of the wafer cassette 100 and pulling it out of a wafer cassette pod upwards, that is to say the expansion/collapsing structure 200 is moved to an expanded state, as can be seen from illustration (a) in FIG. 3.

As is illustrated in FIG. 3, according to one exemplary embodiment, the expansion/collapsing structure 200 may have at least one two-armed joint structure 201, whose two ends can be supported on respectively mutually facing sides of two mutually adjacent shelf sections 111. As is illustrated in illustration (a), the two-armed joint structure 201 can be unfolded completely, so that the two joint arms of the joint structure 201 are in line with one another and, as is illustrated in illustration (c), can be folded up, so that the two joint arms of the joint structure 201 include a specific defined angle. For example, it is possible to provide for a detachable latching structure to be formed between the two arms in the joint, in order to maintain the position in which the joint arms are in line with one another. It is also possible to provide for a movement limiting element 203 to be arranged on each of the respectively mutually facing sides of two mutually adjacent shelf sections 111, with these elements 203 being aligned with respect to one another such that a minimum pitch is maintained between respectively mutually adjacent shelf sections 111 by these elements 203 when the wafer cassette 100 is folded up. The movement limiting elements 203 illustrated in FIG. 3 may also be arranged at a position other than that shown, such as adjacent to the joint points on which the joint structure 201 is supported. Purely as a precaution, it should be mentioned at this point that the joint structure 201 is positioned between the shelf sections 111 such that the wafers 1 supported on the rest or supporting sections 113 of the shelf sections 111 do not make contact with the joint structure 201. In order to keep the development of wear particles during expansion/collapsing as small as possible, the material of the two-armed joint structure 201 may, for example, have carbon fiber, a suitable plastic or a correspondingly low-wear metal.

By way of example, a torsion spring 208 can also be arranged instead of the expansion/collapsing structure 200 in the form of the two-armed joint structure 201, as is illustrated schematically in the illustration (d) in FIG. 3, in which case the two limbs of the unloaded torsion spring 208 can be aligned at right angles to one another (as in illustration (a)) when the wafer cassette 100 is in the expanded state, and in which case the limbs of the torsion spring 208 can include a corresponding angle (see illustration (c)) between them by application of pressure to the wafer cassette 100 on reaching a minimum pitch between the respective shelf sections 111. The material of the torsion spring 208 may, for example, be carbon fiber, a suitable plastic or a metal which is suitable for this purpose.

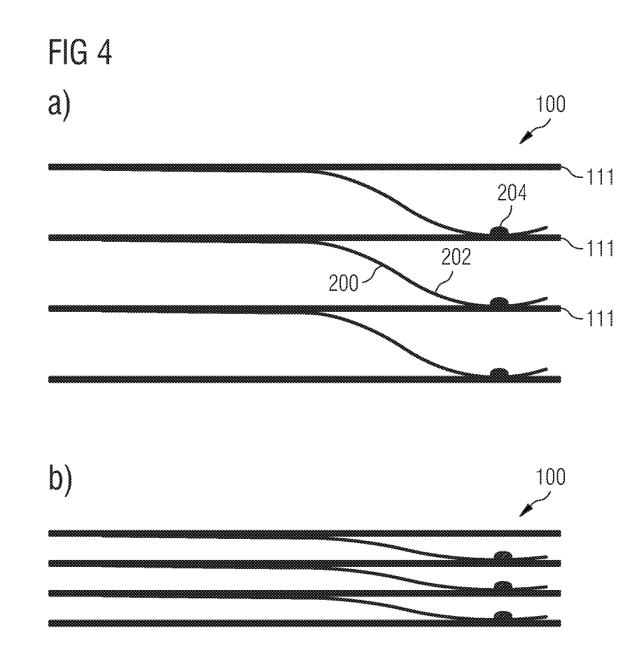

According to another embodiment of the invention, as illustrated in FIG. 4, the expansion/collapsing structure 200 has at least one spring element 202, which is supported between the mutually facing sides of two mutually adjacent shelf sections 111. The spring element 202 whose material, for example, may have carbon fiber or carbon nanotubes filled with polymer, or a correspondingly low-wear metal, is fixed by one of its end sections, for example by means of a rivet 204, on one shelf section 111, while its other end section is supported, such that it can move, on the correspondingly facing side of the adjacent shelf section 111. By way of example, the spring elements 202 may be arranged between the shelf sections 111 as illustrated in FIG. 2B so that, on the one hand, the spring elements 202 do not make contact with the wafer while, on the other hand, there is sufficient space for movement of the non-fixed end section of the spring element 202 along the corresponding shelf section side. The spring element 202 may be designed such that the expanded wafer state 100, as is illustrated in the illustration (a) in FIG. 4, has a “normal state”, that is to say the spring element 202 and therefore the expansion/collapsing structure 200 for removal/insertion of the wafer from/into the wafer cassette 100 is not stressed, and pressure must be applied to the wafer cassette 100 in order to move the wafer cassette 100, as is illustrated in illustration (b) in FIG. 4, to a collapsed state, as could be done, for example, on insertion of the wafer cassette 100 into a wafer cassette pod.

According to another exemplary embodiment of the invention, as illustrated in FIG. 5, the expansion/collapsing structure 200 has at least one scissors type-joint structure 205. The scissors type-joint structure 205 which, by way of example, has two arms, is designed such that one end section of in each case one of the two scissors type-joint arms is fixed to mutually facing sides on in each case one of the shelf sections 111, while the respective other end section of the scissors type-joint arms is supported, such that it can move, on the respectively opposite shelf section, for example in a guide. A compression-spring element 206 can be arranged in the joint area of the two crossing scissors type-joint arms of the two-armed shear-joint structure 205, forcing the two scissors type-joint arms apart from one another when no pressure is applied to the wafer cassette 100, so that, as is illustrated in illustration (a) in FIG. 5, the wafer cassette 100 is in an expanded state. In order to ensure that the respectively mutually adjacent shelf sections 111 and therefore the wafers 1 supported on the shelf sections 111 have a precisely predetermined pitch between them when the wafer cassette 100 is in the expanded state, limiting elements (not illustrated) can be provided, defining the maximum angle and the minimum angle included between the two scissors type-joint arms. When pressure is applied to the wafer cassette 100 from above or below, the compression-spring element 206 can be compressed, with the two scissors type-joint arms of the two-armed scissors type-joint structure 205 being folded up, as is illustrated in illustration (b) in FIG. 5, thus making it possible to precisely fix a minimum pitch between the respectively mutually adjacent shelf sections 111 by means of the compression-spring element 206 or the already mentioned limiting element.

Instead of the compression-spring element 206, a tension-spring element 207 can be arranged between the two crossing scissors type-joint arms of the two-armed scissors type-joint structure 205, pulling the two scissors type-joint arms together when no pressure is applied to the wafer cassette 100, so that the wafer cassette 100, as is illustrated in illustration (a) in FIG. 5, is in an expanded state. The minimum pitch between the respectively mutually adjacent shelf sections 111 can likewise, for example, also be determined precisely by a limiting element when using the tension-spring element 207, in which case the limiting element may, for example, be formed by sections of the joint structure of the two crossing scissors type-joint arms.

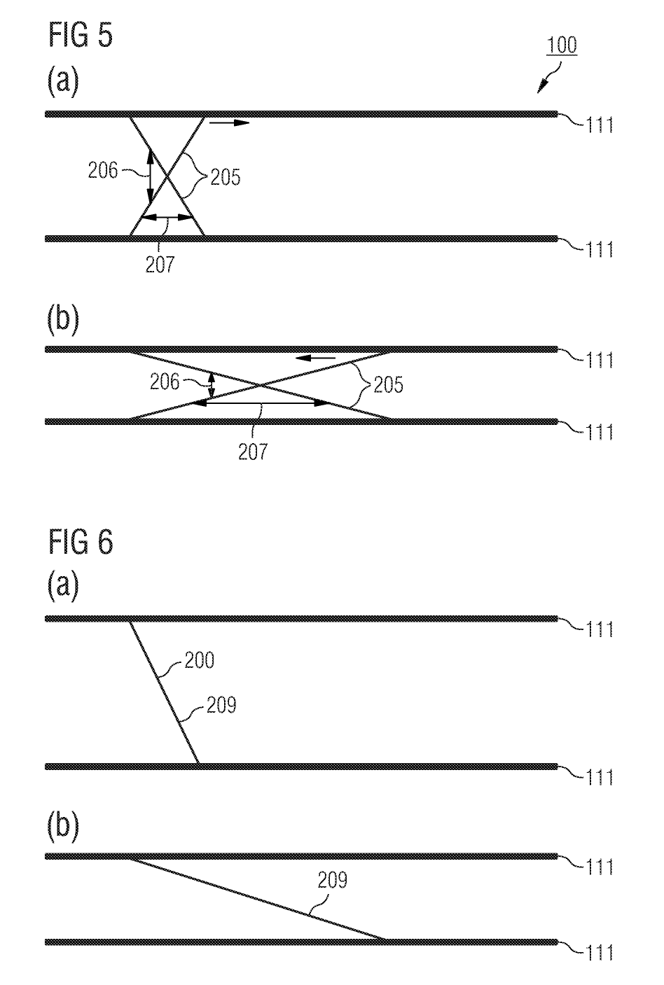

According to another exemplary embodiment of the invention, as illustrated in FIG. 6, the expansion/collapsing structure 200 has at least one single-armed joint structure, with the two end sections of a joint arm 209 which is formed by an intrinsically stiff connecting strut being supported in a hinged manner or such that the end sections can rotate on their mutually facing sides on in each case one of two mutually adjacent shelf sections 111. When the joint arm 209 is in the position illustrated in illustration (a) in FIG. 6, the shelf sections 111 and therefore the wafers supported on them have precisely that pitch between them which is required for automated removal/insertion of the wafers, which means that, in illustration (a), the wafer cassette is in its completely expanded state, and the robot access areas to the individual wafers are aligned precisely with one another. The pitches between the shelf sections 111 can be adjusted by relative rotation of one shelf section 111 with respect to the shelf section 111 that is adjacent to it by the capability to rotate the joint arm 209 with its end sections in the corresponding joint, so that the robot access areas for the individual wafers are positioned offset with respect to one another when the wafer cassette is in the collapsed state. In order to define a precise pitch between respectively mutually adjacent shelf sections 111, the joints in which each of the joint arms 209 are supported in a hinged manner are provided with corresponding movement limiting devices. The joint arms 209 between the individual shelf sections 111 may, for example, be designed such that one shelf section 111 is in each case rotated between the two respective shelf sections adjacent to it, during collapse relative to the two shelf sections 111 adjacent to it. In this embodiment, it is also possible to provide for the free outer circumference of the shelf sections 111 to describe essentially a section of a circular arc, rather than a rectangle or square. Since the joint arm 209 can be rotated for adjustment of the pitch of the shelf sections 111 in, for example, sealed joint capsules (not illustrated), this arrangement makes it possible to achieve essentially particle-free pitch adjustment.

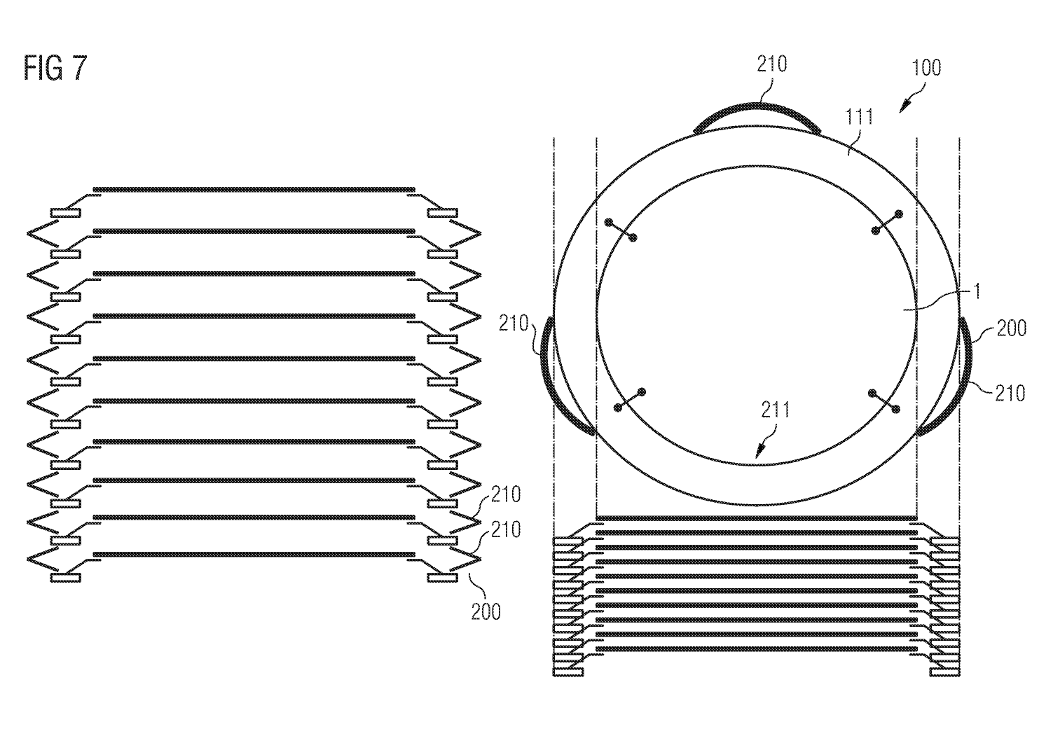

In the exemplary embodiment of the invention illustrated in FIG. 7, the expansion/collapsing structure 200 has a different joint structure, which essentially has a two-armed joint 210, each of whose two free end sections are arranged in a hinged manner on one of two mutually adjacent shelf sections. In contrast to the exemplary embodiment illustrated in FIG. 3, the joint section is moved outwards between the two joint arms 210, that is to say away from the wafers 1, when the wafer cassette 100 is compressed. As can also be seen from FIG. 7, three two-armed joints 210 are in each case provided between two mutually adjacent shelf sections 111 and are arranged distributed around the circumference of the wafer cassette 100 such that a sufficiently large robot access area 211 is provided from at least one side, in order, for example, to use, e.g., one or more end effectors of one or more robot arms to remove the wafers from and to insert them into the wafer cassette 1 00. As they move towards one another, that is to say when the shelf sections 111 of the wafer cassette 100 are collapsing, the joint sections of the joint structure are moved outwards, so that the expansion/collapsing structure 200 is folded outwards in a similar manner to an accordion bellows.

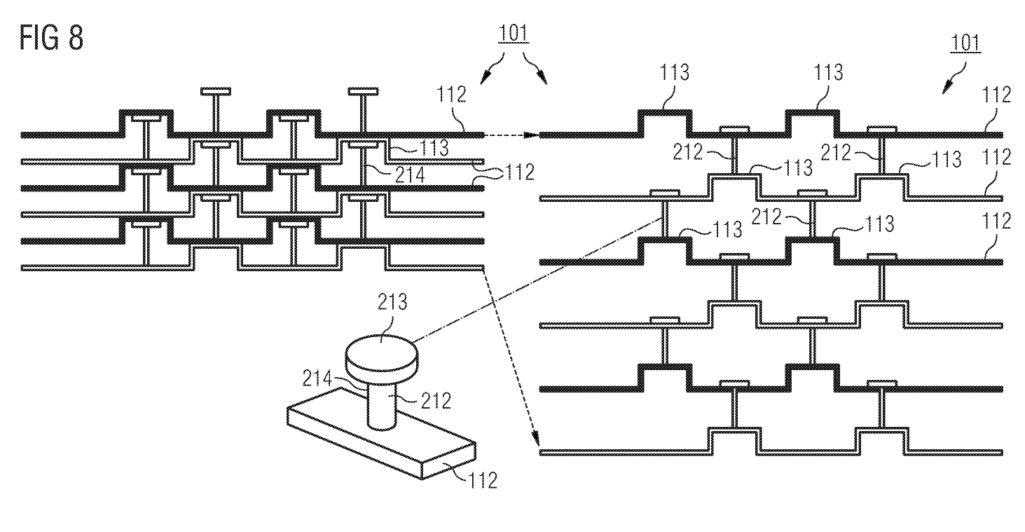

In the further exemplary embodiment, illustrated in FIG. 8, the schematically illustrated expansion/collapsing structure 200 has at least one essentially mushroom-shaped spacer 212, which interacts with shelf sections 112 of the wafer cassette 101, in which case the mushroom-shaped spacers 212 may each, for example, have a stem 214 in the form of a pin and a cap 213 in the form of a disk, square or polygon. At least in the area in which the at least one expansion/collapsing structure 200 is arranged, each of the shelf sections 112 of the wafer cassette 101 has, for example, two stepped sections 113 which are offset upwards relative to the plane of the shelf sections 112 on which the wafers are supported, and have a predetermined pitch between them. In this case, the stepped sections 113 of one of the shelf sections 112 is arranged offset with a gap relative to the stepped sections 113 of the respectively adjacent shelf section 112, as can be seen from FIG. 8. In other words, one of the stepped sections 113 of one of the shelf sections 112 is in each case located under or above a section of the respectively adjacent shelf section 112 on which no stepped section 113 is positioned, with the stepped sections 113 of the shelf section 112 which is then the next being positioned directly under or directly above the stepped sections 113 of the next but one shelf section 112 in the vertical direction. One of the mushroom-shaped spacers 212 is in each case attached by the free end of its stem 214 to the stepped sections 113, while its other end extends, such that it can be moved through an aperture opening in the shelf section 112 arranged above it. The cap 213, which is in the form of a disk, square or polygon, is arranged at the other end of the stem 214, projecting out of the aperture opening, and prevents the stem end from emerging out of the aperture opening.

When the wafer cassette 101 is in the expanded state, the cap 213, which is in the form of a disk, square or polygon, is supported by its lower face, facing the stem 214, on the shelf section 112, through which the stem 214 extends. This results in the mushroom-shaped spacer 212 being used on the one hand as a vertical guide and on the other hand as a pitch limiting means, by means of which the maximum vertical pitch between the mutually adjacent shelf sections 112 which support the wafers is defined, in which case this maximum pitch may correspond to that pitch which is required for handling of the wafers. When the wafer cassette 101 is in the collapsed state, the stem 214 of the spacer 212 extends sufficiently through the aperture opening in the shelf section 112 arranged above it that the upper face of the stepped section 113 rests on the lower face of this shelf section 112, with the cap-side end of the mushroom-shaped spacer 212 extending into the outward-curved lower face of that stepped section 113 which is formed in that shelf section 112 which is then the next but one in the arrangement, and is located directly above the stepped section 113 to which the stem-end of the mushroom-shaped spacer 212 is attached. As can be seen from the collapsed illustration of the wafer cassette 101 in FIG. 8, the pitch between the shelf sections 112 which support the wafer can be reduced down to an extent which is predetermined by the height of the stepped sections 113, by virtue of the described configuration of this exemplary expansion/collapsing structure 200.

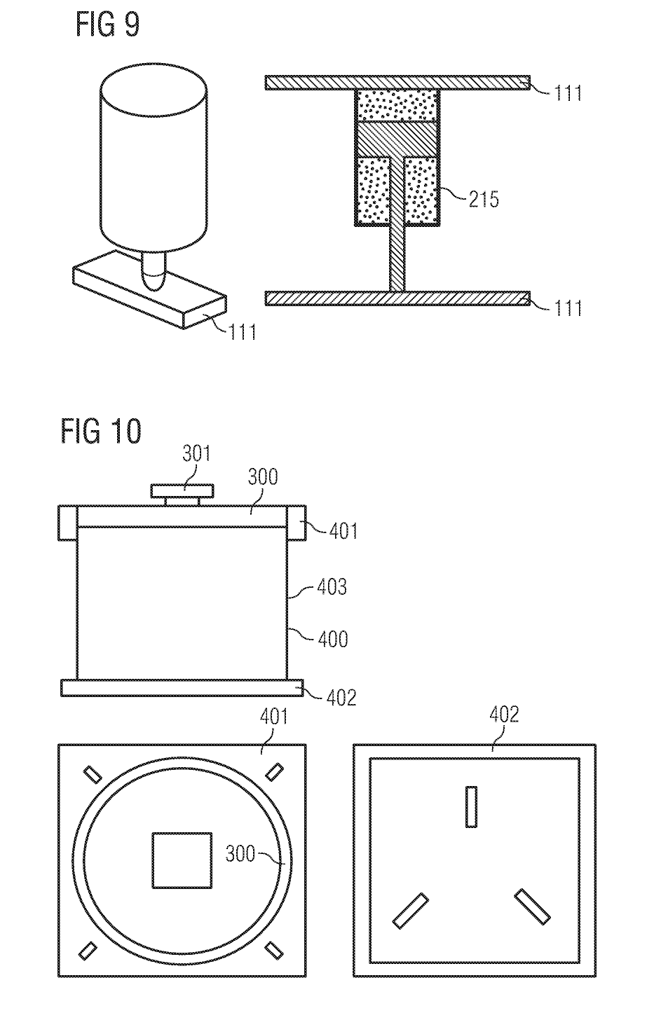

According to the further exemplary embodiment, as illustrated in FIG. 9, the expansion/collapsing structure 200 has at least one damper element 215, whose two end sections are each supported on one of two mutually adjacent shelf sections 111, and has a piston rod, a cylinder and a piston which is connected to the piston rod and is held such that it can move in the cylinder. The free upper face of the cylinder of the damper element 215 is fixed to one shelf section 111, and the free end section of the piston rod is fixed to that shelf section 111 which is adjacent to it. The pitch between the two shelf sections 111, and in consequence the pitch between the wafers supported on the shelf sections 111, can be adjusted within a predetermined range by movement of the piston in the cylinder.

Material which produces few wear products in order to reduce the production of particles are in each case used for some or for all of the described embodiments of the expansion/collapsing structure 200, for example for those structures which allow the elements to slide on one another. Furthermore, the elastic spring structures have a shape and spring force such that even that spring structure which is arranged at the lowest point reaches its expanded state when a wafer is supported on each of the shelf sections that are provided for this purpose, and no additional pressure is exerted on the wafer cassette. This means that the wafer cassette can always expand completely, with the pitch which is predetermined by the expansion/collapsing structure for handling of the wafers being set between the individual wafers. The embodiments illustrated in FIGS. 3 to 9 represent only a limited choice of exemplary embodiments of an expansion/collapsing structure 200, however, whose configuration is not, however, restricted to the illustrated exemplary embodiments.

According to a further exemplary embodiment of the invention, the wafer cassette 100 has at least one closure plate 300 which is coupled at least to the wafer support adjacent to it, that is to say for example to the shelf section 111 adjacent to it. The closure plate 300 illustrated schematically in FIG. 3 is coupled to the top shelf section 111 in the illustration, and is formed essentially by a round-circular plate, whose diameter is larger than the width extent of the shelf sections 111. However, it is also possible for the closure plate 300′, as is likewise illustrated in FIG. 3, to be connected to the lowest shelf section 111 in the illustration. For example, the closure plate 300 or the closure plate 300′ may also be rectangular or square. The closure plate 300 or 300′ for the wafer cassette 100 may be designed for coupling to a door (not illustrated) of a wafer cassette pod 400 (FIG. 10) into which the wafer cassette 100 can be inserted. The closure plate 300 or 300′ of the wafer cassette 100 may, for example, also be designed such that it is suitable for closure of a wafer cassette pod 400 (FIG. 10), so that there is no need to provide an additional door in order to close the wafer cassette pod 400. In the collapsed state, the wafer cassette 100 can be inserted into the wafer cassette pod 400, in which case the wafer cassette pod 400 can be closed, for example in a sealed form, by means of the closure plate 300 or 300′.

The configuration of the wafer cassette 100 with an expansion/collapsing structure 200 allows the wafer cassette 100 to be folded up into the wafer cassette pod 400 during its use, by the side of the wafer cassette 100 which faces away from the closure plate 300 being inserted into the wafer cassette pod 400, which is open on one side, until the closure plate (which may also be referred to as a door) 300 reaches a doorframe, which is formed on the wafer cassette pod, and can be supported on it, and locked to it, with the wafer cassette pod 400 being closed. When it is intended to remove the wafer cassette 100 from the wafer cassette pod 400, the door 300 can be pulled away from the doorframe of the wafer cassette pod after the closure plate 300 has been unlocked, in which case the wafer cassette 100 can expand by virtue of the expansion/collapsing structure 200 arranged there.

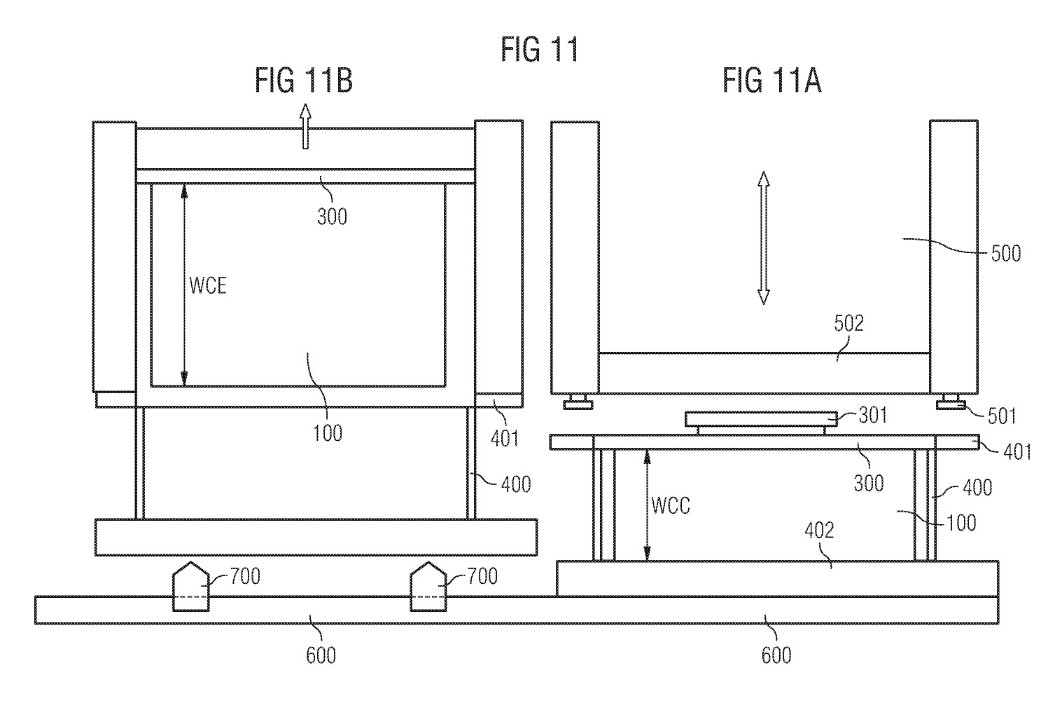

In other words, exemplary embodiments of the invention cover a wafer cassette pod 400 which is designed for docking with a minienvironment chamber loadport (FIG. 11A) and can be closed in a sealed manner, with a wafer cassette 100 being held in it, by means of a closure plate (door) 300 arranged on the wafer cassette 100, with the wafer cassette 100 having a wafer support in order to support a batch of wafers 1, and with the wafer support structures each being coupled to an expansion/collapsing structure 200 such that the pitch between wafers 1 supported by means of the wafer support structures is variable.

According to one exemplary embodiment, as illustrated in FIG. 10, the wafer cassette pod 400 may be a top opening pod (TOP), whose upper closure cover, which may also be referred to as a so called top domain, is formed by a cover 401. The wafer cassette pod 400 in the form of a top opening pod (TOP) has a podshell 403 whose cross section is essentially square or round, an essentially rectangular or square baseplate 402 on the lower face of the podshell 403, and the cover 401, which is for example essentially in the form of a plate, which is supported on the upper face of the podshell 403 and in which an opening for insertion/removal of the wafer cassette 100 is formed, with the cover 401 essentially having a rectangular or square outer contour. The opening, which is round according to this exemplary embodiment, in the cover 401 is surrounded by a frame in which the round door 300, which closes the opening, for the wafer cassette 100 can be supported such that it is sealed. The TOP 400 can be closed, such that it is sealed, by means of the door 300, which may be supported on the frame surrounding the opening, thus preventing particles from the surrounding area from entering the wafer cassette pod 400. A locking structure is formed between the door 300 and the frame of the cover 401 and, for example, may have latches (not illustrated), by means of which the closure plate 300 can be locked and unlocked relative to the frame of the cover 401.

By way of example, the baseplate 402 on the lower side (which may also be referred to as a so called bottom domain) of the TOP 400 may be designed such that it can interact with a conveyor 600 (FIG. 11) which, by way of example, is in the form of a roll conveyor, and on which the TOP 400 can be transported between individual process stations.

The closure plate (door) 300 of the wafer cassette 100 which closes the opening in the cover 401 of the TOP can be provided on its free upper face with coupling means 301, which are designed for coupling to an interface device of the minienvironment chamber 500 (FIG. 11).

Although this is not shown in the drawing, the wafer cassette pod 400 according to one exemplary embodiment may also be in the form of a standardized mechanical interface pod (SMIF pod per SEMI E119.1-5) in which a collapsed wafer cassette can be held, with the base closure plate (door) of the SMIF pod in an embodiment such as this having an opening for insertion/removal of the wafer cassette, which opening can be sealed by means of the door 300′ arranged on the lower face of the wafer cassette. Once the SMIF pod has docked at the loadport of the minienvironment chamber above which the SMIF pod is positioned and the loadport has subsequently been coupled to the door 300′, a locking structure, which is provided between the loadport and the door 300′ of the wafer cassette, can be released. The wafer cassette together with the wafers supported in it can be moved into the minienvironment chamber by lowering the interface device of the minienvironment chamber together with the door 300′ of the wafer cassette coupled to it, with the wafer cassette expanding while the door is being lowered, that is to say with the pitch between the mutually adjacent wafers being increased by means of the expansion/collapsing structure such that the wafer cassette can then be completely unfolded or expanded within the minienvironment chamber. By way of example, the wafer cassette can be expanded by the expansion/collapsing structure having a spring structure which forces the shelf sections apart from one another, or by the wafer cassette being held on its face opposite the closure plate 300′ against an upper edge of the minienvironment chamber such that the expansion/collapsing structure is expanded in order to increase the pitch between the wafers.

After processing the wafers, the wafer cassette can be pushed into the SMIF pod again by upward movement of the interface device of the minienvironment chamber together with the closure plate 300′ of the wafer cassette coupled to it, with the expansion/collapsing structure collapsing, thus reducing the pitch between the shelf sections supporting the wafers.

FIG. 11 shows a schematic illustration of a minienvironment loadport arrangement according to one exemplary embodiment of the invention, with FIG. 11A showing a state before the wafer cassette pod has docked with the loadport, and FIG. 11B showing a state after a wafer cassette pod has docked with the loadport.

The loadport arrangement has a minienvironment chamber 500 with a wafer cassette pod loadport (loadlock, pod opening interface) 502 and a wafer cassette pod 400 which is designed for docking with the wafer-cassette pod loadport 502, with the wafer cassette pod 400 holding a wafer cassette 100 which is provided with a plurality of wafer support structures in order to support wafers 1, with the wafer support structures being designed such that the pitch between wafers 1 supported by means of the wafer support structures is variable.

According to the exemplary embodiment illustrated in FIG. 11, the loadport arrangement has a minienvironment chamber 500 with a robot access area (not illustrated). Separated by a clearance below the loadport, FIG. 11A shows a TOP 400 (top opening pod) which has been transported by means of a transport device which, for example, may be in the form of a roll conveyor 600 to the illustrated position, and has been positioned by means of positioning devices at the predetermined position, which is suitable for the TOP 400 to dock with the loadport. The TOP 400 corresponds essentially to the TOP 400 described with reference to FIG. 10 and has the baseplate 402, which interacts with the conveyor 600, and the cover 401. The TOP 400 holds a collapsed wafer cassette 100 which contains a number of wafers corresponding to the predetermined batch. For expansion/collapsing, the wafer cassette 100 has an expansion/collapsing structure which, by way of example, may be designed according to one of the embodiments described in FIGS. 3 to 9.

On its top domain facing the loadport, the TOP 400 is closed by means of a door 300, which corresponds to the closure plate 300, of the wafer cassette 100 which is supported, such that it is sealed, on the frame of the cover 401 surrounding the opening (not shown). If, as is illustrated in FIG. 11A, the wafer cassette 100 is located entirely within the TOP 400, the wafer cassette 100 can have a minimal vertical extent WCC.

For the TOP 400 to dock with the loadport, the loadport has on its lower face, facing the TOP 400, a docking structure 501 designed to interact with docking sections on the cover 401 and aligned appropriately with the docking sections of the cover 401 of the TOP 400 once the TOP 400 has been positioned in the docking position by means of the conveyor 600. The docking structure 501 of the loadport and the docking sections of the cover 401 are each designed such that they can engage with one another, that is to say the TOP 400 and the loadport can be connected to one another, with their respective interfaces being aligned.

The TOP 400 with its docking sections on the cover 401 is moved to the docking structure 501 of the minienvironment chamber 500 by lifting the TOP 400 by means of a lifting structure 700 (FIG. 11B) which, for example, is provided on the conveyor. On reaching the docking position, the docking sections of the TOP 400 and the docking structure 501 of the minienvironment chamber 500 are engaged with one another in a controlled manner. The deliberate docking of the TOP 400 with the loadport results in the door 300 (which closes the TOP) of the wafer cassette 100 and the wafer cassette pod loadport (loadlock, pod opening interface) 502 of the loadport being aligned with one another.

An interface device (not illustrated) of the wafer cassette pod loadport 502 is used to mechanically couple the wafer cassette pod loadport 502 to the coupling flange 301 arranged on the upper face of the closure plate 300. Once this has been done, the interface device can be used to unlock the locking structure (which is, for example, mechanical), by means of which the closure plate 300 is kept locked relative to the frame of the cover 401 and, for example, may have latches. Once the locking structure has been unlocked, the wafer cassette 100 held in the TOP 400 can be removed from the TOP 400 that has been docked with the loadport. During this process, the interface device of the wafer cassette pod loadport 502 is moved or lifted upwards into the minienvironment chamber 500 together with the closure plate 300, coupled to it, of the wafer cassette 100, and the wafer cassette 100 expands within the minienvironment chamber 500, as is illustrated schematically in FIG. 11B, such that the wafers which are supported on the wafer supports in the wafer cassette 100 have a pitch with respect to one another within the minienvironment chamber 500 such that, for example, one or more end effectors of one or more robot arms of a handling device can access a wafer in the access area without adversely affecting a wafer arranged adjacent to it. This means that the wafer cassette 100 may have a maximum vertical extent WCE (FIG. 11B) within the minienvironment chamber 500. In this embodiment of the minienvironment chamber arrangement, the expansion/collapsing structure 200 of the wafer cassette 100 can be designed such that it expands solely on the basis of the force of gravity, and the predetermined pitch between the wafers can be set without any elastic assistance. If, after processing of the wafer, the wafer cassette 100 is inserted back into the docked TOP 400 again by means of the interface device 502, with the door 300 and the wafer supports, which are coupled thereto with the aid of the expansion/collapsing structure 200, being moved away, the expansion/collapsing structure 200 can collapse by virtue of its design and its own weight.

By way of example, the chamber 500 is a minienvironment, with suitable means being provided to prevent the contamination from the ambient environment when the wafer cassette 100 is being moved into the minienvironment chamber 500 of the loadport.

As can be seen from FIG. 11B, the lifting structure 700 for lifting of the TOP 400 for docking with the loadport is a component of the transport device, such as a roll conveyor 600. However, it is also possible for the lifting structure for lifting the TOP 400 for docking with the loadport to be, for example, a component of the wafer cassette pod loadport 502. It is also possible to provide for the TOP 400 to be supported by the lifting structure 700 throughout the entire time for which it is docked, or else it is possible to provide for the lifting structure 700 to be released from the TOP 400 after it has docked with the minienvironment chamber 500, so that the TOP 400 is held against the minienvironment chamber 500 only by means of its coupling connection to the minienvironment chamber 500. However, if the aim is to avoid the TOP 400 being held suspended on the minienvironment chamber 500 just be means of its coupling connection, holding means (not illustrated), for example, can additionally be arranged on the TOP 400 and/or on the minienvironment chamber 500, acting on the TOP 400 and the minienvironment chamber 500, for example on its side area.

According to a further exemplary embodiment, which is not illustrated, it is possible for the clearance between the upper face of the transport device and the lower face of the TOP 400 docked with the loadport to be sufficiently large that further TOPs can be transported or conveyed along the transport device without making contact with the TOP 400 docked with the minienvironment chamber 500.

According to one exemplary embodiment of the invention, the advantage of the wafer cassette 100 may, for example, be that the wafer cassette 100 for storage and transportation of wafers can be held collapsed in a pod, thus making it possible to effectively reduce the space required for storage of wafer cassettes fitted with wafers. Furthermore, the number of wafer cassettes in a factory can be reduced since they can hold a greater number of wafers than those conventional wafer cassettes in which the wafers are stacked with a pitch between one another as required for handling of the wafers, so that the wafer cassette, according to one exemplary embodiment of the invention is advantageous, for example, for 300 mm or 450 mm wafers. Since, by virtue of its expansion/collapsing structure, the wafer cassette 100 can expand precisely during removal from the pod, the wafer cassette can in consequence provide sufficient space between the wafers for them to be handled.

One advantage of the TOP (top opening pod) 400 into which a wafer cassette 100 according to one exemplary embodiment of the invention can be inserted is, for example, that it has the opening for insertion/removal of the wafer cassette 100 on its top domain, and the closure for closing this opening is provided by a cover plate 300 which is a component of the collapsible wafer cassette 100 which can be inserted into the TOP and removed from it, with the baseplate of the TOP being designed, for example, for interaction with a conveyor. A locking structure can be arranged for sealed closure of the TOP with the cover plate (door) 300 of the wafer cassette 100 in the area of the top domain of the TOP, which forms its loadport interface, and can be opened and closed by interaction with a pod opening interface of the minienvironment chamber loadport.

The minienvironment chamber loadport arrangement with a minienvironment chamber and a TOP (top opening pod) according to one exemplary embodiment of the invention is distinguished, for example, by the advantage that the loadport has a pod opening interface on its lower side, facing a coupling device that is formed in the top domain of the TOP, with the TOP holding a collapsed wafer cassette which expands on being moved into the minienvironment chamber and collapses on being moved back into the TOP. Since the TOP can be transported with its baseplate, supported on an underground conveyor, to a predetermined position underneath the minienvironment chamber, and the docking with the pod opening interface of the minienvironment chamber takes place after lifting of the TOP, it is possible to avoid particles caused by wear, which are formed on the lower face of the TOP as a result of the underground transportation, from entering the minienvironment chamber. By way of example, the minienvironment chamber loadport arrangement may be provided with a lifting structure which is designed to lift the TOP from the transport device to the minienvironment chamber on the transport device or on the minienvironment chamber in the area of its loadport. For example, it is possible to provide for a sufficient amount of free space to be provided between the lower side of the TOP docked with the loadport and the plane of the conveyor that the next following TOP can be passed through under the docked TOP. The TOP can be transported with its baseplate on an underground conveyor to the respective process station, which may be advantageous in comparison to the use of ceiling conveyors using rails, in the form of a hoist based automated material handling system (hoist-based AMHS) since an underground conveyor allows a better throughput, in which case the underground transportation utilized the floor space of raised floor also as a flat stocker.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A wafer cassette, comprising:
a plurality of wafer support structures for supporting wafers, wherein the wafer support structures are designed such that a pitch between wafers supported by means of the wafer support structures is variable.

2. The wafer cassette as claimed in claim 1, wherein each of the wafer support structures has a shelf section for supporting one wafer, and wherein mutually adjacent shelf sections are coupled by means of an expansion/collapsing structure such that the pitch between respectively mutually adjacent wafers can be adjusted at right angles to a wafer surface within a predetermined pitch range.

3. The wafer cassette as claimed in claim 1, wherein each of the wafer support structures has a shelf section for supporting one wafer, and wherein mutually adjacent shelf sections are coupled by means of an expansion/collapsing structure such that a size of the wafer cassette at right angles to a wafer surface can be adjusted between a minimum and a maximum extent.

4. The wafer cassette as claimed in claim 2, wherein the shelf sections are designed such that the wafers can be supported on the shelf sections by means of bevels/edge exclusion zones.

5. The wafer cassette as claimed in claim 2, wherein one end section of the expansion/collapsing structure is supported on respectively mutually facing sides of two mutually adjacent shelf sections.

6. The wafer cassette as claimed in claim 5, wherein the expansion/collapsing structure has at least one joint structure.

7. The wafer cassette as claimed in claim 6, wherein the joint structure has a two-armed joint structure.

8. The wafer cassette as claimed in claim 5, wherein the expansion/collapsing structure has at least one spring element.

9. The wafer cassette as claimed in claim 5, wherein the expansion/collapsing structure has at least one scissors type-joint structure.

10. The wafer cassette as claimed in claim 2, wherein the expansion/collapsing structure has at least one damper element with two end sections supported on one of two mutually adjacent shelf sections.

11. The wafer cassette as claimed in claim 2, further comprising spacers arranged on the shelf sections, the spacers setting a minimum pitch between mutually adjacent wafers.

12. The wafer cassette as claimed in claim 2, further comprising at least one closure plate coupled at least to the wafer support structure adjacent to it.

13. The wafer cassette as claimed in claim 12, wherein the at least one closure plate is designed for coupling to a door of a wafer cassette pod.

14. The wafer cassette as claimed in claim 12, wherein the closure plate is designed as a door to close a wafer cassette pod.

15. The wafer cassette as claimed in claim 12, wherein the wafer cassette, in the collapsed state, can be inserted into the wafer cassette pod for sealed closure of a wafer cassette pod by means of the closure plate.

16. The wafer cassette as claimed in claim 2, wherein the wafer cassette is designed such that it can be collapsed on insertion into a wafer cassette pod and can be expanded on removal from the wafer cassette pod.

17. A wafer cassette pod that is designed for docking with a minienvironment chamber loadport and that can be closed by means of a closure plate by accommodating a wafer cassette, the closure plate being arranged at the wafer cassette,
wherein the wafer cassette has a plurality of wafer support structures for supporting wafers; and
wherein each of the wafer support structures is coupled to an expansion/collapsing structure such that a pitch between wafers supported by means of the wafer support structures is variable.

18. The wafer cassette pod as claimed in claim 17, wherein the wafer cassette pod is a top opening pod whose closure cover is formed by the closure plate designed as a door of the wafer cassette.

19. The wafer cassette pod as claimed in claim 18, wherein the wafer cassette which is held in the wafer cassette pod is in a collapsed state.

20. The wafer cassette pod as claimed in claim 18, wherein the door of the wafer cassette is designed for coupling to an interface device of the minienvironment chamber loadport, which interface device can pull the door into a minienvironment chamber, with the wafer cassette expanding after sealed docking of the wafer cassette pod to the minienvironment chamber.

21. The wafer cassette pod as claimed in claim 20, wherein the wafer cassette is expanded by force of gravity.

22. The wafer cassette pod as claimed in claim 17, wherein the wafer cassette pod is a standardized mechanical interface pod per SEMI E19.x whose bottom door holds the wafer cassette.

23. The wafer cassette pod as claimed in claim 22, wherein the wafer cassette that is held in the wafer cassette pod is in a collapsed state.

24. The wafer cassette pod as claimed in claim 22, wherein the door of the wafer cassette is designed for coupling to an interface device of the minienvironment chamber loadport, which interface device can pull the door into a minienvironment chamber, with the wafer cassette expanding after docking of the wafer cassette pod to the minienvironment chamber loadport.

25. The wafer cassette pod as claimed in claim 24, wherein the wafer cassette is held at its side opposite the door against an upper edge of the minienvironment chamber loadport for expansion.

26. The wafer cassette pod as claimed in claim 17, wherein the wafer cassette pod is in the form of a mini environment.

27. A minienvironment chamber loadport arrangement, comprising:
a minienvironment chamber having a wafer cassette interface; and
a wafer cassette pod designed for docking with the minienvironment chamber, wherein the wafer cassette pod holds a wafer cassette provided with a plurality of wafer support structures for supporting wafers, the wafer support structures designed such that a pitch between wafers supported by the wafer support structures is variable.

28. The minienvironment chamber loadport arrangement as claimed in claim 27, wherein the wafer cassette pod has a frame designed for docking with a loadport of the minienvironment chamber and within which a closure plate, which closes the wafer cassette pod, of the wafer cassette is supported.

29. The minienvironment chamber loadport arrangement as claimed in claim 28, wherein, in order to open the wafer cassette pod, an interface device of the minienvironment chamber loadport can be coupled to the closure plate designed as a door of the wafer cassette pod.

30. The minienvironment chamber loadport arrangement as claimed in claim 28, wherein the closure plate of the wafer cassette pod is held sealed in the frame of the wafer cassette pod by means of a locking structure, which can be unlocked from the interface device in order to remove the wafer cassette from the wafer cassette pod.

31. The minienvironment chamber loadport arrangement as claimed in claim 28, wherein the wafer cassette pod is a top opening pod such that, once the wafer cassette pod has been docked with the minienvironment chamber loadport, which is formed on the lower face of the minienvironment chamber, the closure plate of the wafer cassette can be pulled into the minienvironment chamber by means of the interface device of the minienvironment chamber with the wafer cassette expanding.

32. The minienvironment chamber loadport arrangement as claimed in claim 28, wherein the wafer cassette pod is a standardized mechanical interface pod (SMIF) such that, after the wafer cassette pod has been docked with the minienvironment chamber loadport, which is formed on the upper face of the minienvironment chamber, the closure plate of the wafer cassette pod can be pulled into the minienvironment chamber by means of the interface device of the minienvironment chamber with the wafer cassette expanding.

33. The minienvironment chamber loadport arrangement as claimed in claim 27, wherein the minienvironment chamber loadport arrangement has a lifting device designed to lift the wafer cassette pod for docking with the minienvironment chamber.

34. The minienvironment chamber arrangement as claimed in claim 27, further comprising a transport device by means of which the wafer cassette pod can be transported to the minienvironment chamber loadport.

35. The minienvironment chamber loadport arrangement as claimed in claim 34, wherein the transport device is a conveyor, and wherein the wafer cassette pod has a baseplate designed to interact with the conveyor.

36. The minienvironment chamber loadport arrangement as claimed in claim 34, wherein the transport device has a lifting structure designed to lift the wafer cassette pod for docking with the minienvironment chamber.

37. The minienvironment chamber loadport arrangement as claimed in claim 34, wherein the wafer cassette interface of the minienvironment chamber has a lifting structure by means of which the wafer cassette pod can be lifted for docking with the minienvironment chamber.

38. The minienvironment chamber loadport arrangement as claimed in claim 36, wherein the transport device is arranged with a vertical clearance underneath the minienvironment chamber such that a further wafer cassette pod can be passed through between a lower face of the wafer cassette pod whose upper face is docked with the minienvironment chamber and the transport device.

39. The minienvironment chamber loadport arrangement as claimed in claim 27, wherein the minienvironment chamber is designed to hold an expanded wafer cassette and has an end effector access area for a wafer handling device.
